(19) United States
(12) Patent Application Publication
(10) Pub. No.: US 2025/0071883 A1
(43) Pub. Date: Feb. 27, 2025

(54) HEAT SPREADING COATING FOR ELECTRONIC ASSEMBLIES

(71) Applicant: ELBIT SYSTEMS LTD, Haifa (IL)

(72) Inventors: Reut BEN ZAKEN (BITTON), Haifa (IL); Itay Theodor SOLOMON, Haifa (IL); Isaac Jak KETTNER, Haifa (IL); Oren BASS, Haifa (IL)

(21) Appl. No.: 18/941,598

(22) Filed: Nov. 8, 2024

Related U.S. Application Data
(63) Continuation of application No. PCT/IL2023/050468, filed on May 8, 2023.

(30) Foreign Application Priority Data
May 9, 2022 (IL) 292893

(51) Int. Cl. H05K 1/02; H05K 3/28

(52) U.S. Cl. CPC H05K 1/0209; H05K 3/284; H05K 2201/0154; H05K 2201/0209; H05K 2201/0323; H05K 2201/09872; H05K 2203/1322

(57) ABSTRACT

An electronic assembly with heat spreading coating is having a PCB carrying conducting traces heat producing electronic components. An electrically isolating polymeric coating is applied over the electric the traces and the heat producing electronic components. The electrically isolating polymeric coating conforms with an irregular structure of the PCB. A heat spreading layer is applied over the polymeric coating. The heat spreading layer comprises: at least one heat spreading zone selected from the group consisting of: a plurality of graphene nano-platelets, a plurality of graphene particles, a plurality of boron-nitride particles, a plurality of graphene flakes, a plurality of boron-nitride flakes, at least one graphene sheets, and combination thereof; and a binder, wherein the electrically isolating polymeric coating adheres to the PCB and covers the electric conducting traces and the heat producing electronic components, and the heat spreading layer conforms to the irregular structure of the polymeric coating.

### TECHNICAL FIELD

The present disclosed subject matter relates to heat spreading coating for electronic circuits, and more particularly, the present disclosed subject matter relates to improving the heat spreading from electronical components while increasing product reliability and reducing the weight and size of the electronical assembly.

### BACKGROUND

Heat dissipation for electronic devices and components mounted on printed circuit board (PCB) is a growing problem as power consumption increases to meet performance requirements. Thick copper or some other conductive metal may be embedded in a PCB or assembled on the PCB to increase heat dissipation. The metals acts as a heat channel or heat sinks for spreader assisting heat distribution over a larger area for faster dissipation.

However, the use of such metallic thermal management solutions adds significant weight to the assembly as well as cost increase. The extra weight is a serious issue for weight-restricted applications such as devices used in aircrafts and spacecraft electronic payload applications.

There is strong incentive to use lighter weight thermal conducting core materials such as aluminum. However, aluminum has half the conductivity of copper so thicker sheet material is required, increasing the volume of the electronic device.

Thus, a need exists for heat spreading materials for electronic devices with improved thermal performance and lighter weight.

### BRIEF SUMMARY

According to an aspect of the present disclosed subject matter, significant improvement of the heat spreading from electronical components is achieved while increase product reliability and reducing the weight and size of the electronical assembly using a plurality of graphene and/or boron-nitride very high thermal conductivity particles, flakes and/or sheets, embedded in elements that already exist on the electronical circuit, such as conformal coating designed to provides electrical insulation and environmental durability performance.

According to an aspect of the present disclosed subject matter, determining and controlling the required thermal properties of an electronical assembly enables the use of higher power consumption of components while improving thermal performance without adding significant weight or size increment to the electronic systems. The product gains higher reliability with the ability to reduce the size and weight of the product using graphene and/or boron-nitride very high thermal conductivity particles, flakes and/or sheets.

It is an aspect of the present subject matter to use graphene in thermally conductive layers over an electronic assembly so as to decrease the permeability characteristic of the polymeric coating and increase dramatically the dielectric resistance, operational integrity, covering and protecting solder joints, the leads of electronic components, exposed traces, and other metallized areas from corrosion, ultimately extending the reliability and working life of the electronic assembly.

It is another aspect of the present subject matter to determine and control the heat transfer pathways over the layers that cover an electronic assembly by planning the placement of the thermally conductive layer and its architectures.

It is another aspect of the present subject matter to dramatically reduce the temperature of highly power consumption components and hot spots placed on an electronic assembly. This can reduce the weight and size of the electronic assembly.

According to a first aspect of the present disclosed subject matter to disclose an electronic assembly with heat spreading coating comprising: a printed circuit board (PCB) having electric conducting traces and at least one heat producing electronic component; an electrically isolating polymeric coating applied over the electric conducting traces and at least one heat producing electronic component, wherein the polymeric coating at least partially covers the PCB, and wherein the polymeric coating conforms with the irregular structure of the PCB; a first heat spreading layer, applied over the polymeric coating, comprises: at least one heat spreading component selected from the group consisting of: a plurality of graphene nano-platelets, a plurality of graphene particles, a plurality of boron-nitride particles, a plurality of graphene flakes, a plurality of boron-nitride flakes, at least one graphene sheets, and combination thereof; and a binder,

In some exemplary embodiments the electrically isolating polymeric coating adheres to PCB and covers the electric conducting traces and at least one heat producing electronic component, and the first heat spreading layer conforms to the irregular structure of the polymeric coating.

In some exemplary embodiments the thickness of the electrically isolating polymeric coating is less than 60 microns.

In some exemplary embodiments the electrically isolating polymeric coating protects the PCB from environmental conditions.

In some exemplary embodiments the electrically isolating polymeric coating is applied using one of: spraying, brushing, dipping, CVD (Chemical vapor deposition), or a combination thereof.

In some exemplary embodiments the thermal conductivity of the first heat spreading layer is more than 3 W m(−1) K(−1).

In some exemplary embodiments the thermal conductivity of the first heat spreading layer is more than 9 W m(−1) K(−1).

In some exemplary embodiments the first heat spreading layer comprises a mixture of at least: one of: a plurality of graphene flakes, and a plurality of boron-nitride flakes; and one of: a plurality of graphene nano-platelets, a plurality of graphene particles, and a plurality of boron-nitride particles.

In some exemplary embodiments the first heat spreading layer comprises a mixture of at least: one of: a plurality of graphene particles, and a plurality of boron-nitride particles, wherein the particles have a range of sizes of between 3 to 35 microns.

In some exemplary embodiments the first heat spreading layer comprises a mixture of at least two of: a plurality of graphene flakes, a plurality of boron-nitride flakes; a plurality of graphene particles, and a plurality of boron-nitride particles.

In some exemplary embodiments the first heat spreading layer comprises a plurality of flakes and a plurality of particles, wherein a plurality of particles are situated in the gaps between the flakes.

In some exemplary embodiments the first heat spreading layer comprises at least one of: a plurality of graphene flakes, and a plurality of boron-nitride flakes, wherein a plurality of the flakes are oriented substantially in the plane of the first heat spreading layer, and a plurality of the flakes partially overlap.

In some exemplary embodiments the plurality of the flakes partially overlaps such that at least three flakes overlap at the same place.

In some exemplary embodiments the first heat spreading layer comprises at least two graphene sheets.

In some exemplary embodiments at least two graphene sheets partially overlap.

In some exemplary embodiments the electronic assembly with heat spreading coating further comprises a plurality of heat producing electronic components, wherein the first heat spreading layer substantially fills the gaps between the of heat producing electronic components and provides a smooth surface away from the PCB.

In some exemplary embodiments the electronic assembly with heat spreading coating further comprises at least a second heat spreading layer applied on the surface of the first heat spreading layer.

In some exemplary embodiments the second heat spreading layer comprises at least one graphene sheet.

In some exemplary embodiments the electronic assembly with heat spreading coating further comprises a protective coating applied over the second heat spreading layer.

In some exemplary embodiments the electronic assembly with heat spreading coating further comprises a binder layer applied between the first heat spreading layer and the second heat spreading layer.

In some exemplary embodiments the electronic assembly with heat spreading coating further comprises a third heat spreading layer.

In some exemplary embodiments the third heat spreading comprises at least one graphene sheet.

In some exemplary embodiments the electronic assembly with heat spreading coating further comprises a protective coating applied over the third heat spreading layer.

In some exemplary embodiments the electronic assembly with heat spreading coating further comprises a binder layer applied between the second and the third heat spreading layers.

In some exemplary embodiments the heat spreading layer spreads the heat generated by the least one heat producing electronic component, wherein, in operation, the temperature of the at least one heat producing electronic component is at least 10 degrees Centigrade below the temperature of the same PCB in which a heat spreading layer was not applied.

In some exemplary embodiments, in operation the temperature of the at least one heat producing electronic component is at least 20 degrees Centigrade below the temperature of the same PCB in which a heat spreading layer was not applied.

In some exemplary embodiments, in operation the temperature of the at least one heat producing electronic component is at least 5% below the temperature of the same PCB in which a heat spreading layer was not applied.

In some exemplary embodiments, in operation, the temperature of the at least one heat producing electronic component is at least 10% below the temperature of the same PCB in which a heat spreading layer was not applied.

In some exemplary embodiments the first layer comprises at least one graphene sheet, and wherein the at least one graphene sheet length and a width between 1 to 10 cm.

In some exemplary embodiments the thickness of the at least one graphene sheet is 0.3 nm.

In some exemplary embodiments the binder of the first heat spreading layer is acrylic binder.

In some exemplary embodiments the binder of the first heat spreading layer is acrylic binder.

In some exemplary embodiments the thickness of the first heat spreading layer is between 30 to 60 microns.

In some exemplary embodiments the first heat spreading layer is a conformal coating comprising 5% (by volume, or alternatively by weight in respect to the binder) graphene nano-platelets mix with acrylic, and the conformal coating layer has thickness between 30 to 60 microns.

In some exemplary embodiments the electronic assembly with heat spreading coating further comprises a protective coating applied over the first heat spreading layer.

In some exemplary embodiments the first heat spreading layer comprises graphene, and wherein the graphene in the heat spreading layer decrease the permeability characteristic of the heat spreading layer to improve and extend the reliability and working life of the electronic assembly.

In some exemplary embodiments the first heat spreading layer comprises at least two non-contiguous heat spreading zones.

In some exemplary embodiments each of the at least two non-contiguous heat spreading zones comprises at least one graphene sheet, such that graphene sheets of different heat spreading zones do not overlap.

Unless otherwise defined, all technical and scientific terms used herein have the same meaning as commonly understood by one of ordinary skill in the art to which this disclosed subject matter belongs. Although methods and materials similar or equivalent to those described herein can be used in the practice or testing of the present disclosed subject matter, suitable methods and materials are described below. In case of conflict, the specification, including definitions, will control. In addition, the materials, methods, and examples are illustrative only and not intended to be limiting.

### BRIEF DESCRIPTION OF THE DRAWINGS

Some embodiments of the disclosed subject matter described, by way of example only, with reference to the accompanying drawings. With specific reference now to the drawings in detail, it is stressed that the particulars shown are by way of example and for purposes of illustrative discussion of the preferred embodiments of the present disclosed subject matter only, and are presented in the cause of providing what is believed to be the most useful and readily understood description of the principles and conceptual aspects of the disclosed subject matter. In this regard, no attempt is made to show structural details of the disclosed subject matter in more detail than is necessary for a fundamental understanding of the disclosed subject matter, the description taken with the drawings making apparent to those skilled in the art how the several forms of the disclosed subject matter may be embodied in practice.

In the drawings:

FIG. 1A schematically illustrates a cross sectional view of an electronic assembly with heat dissipating coating, in accordance with some exemplary embodiments of the disclosed subject matter.

FIG. 1B schematically illustrates a cross sectional view of an electronic assembly with heat dissipating coating, in accordance with some exemplary embodiments of the disclosed subject matter.

FIG. 1C schematically illustrates a cross sectional view of an electronic assembly with heat dissipating coating, in accordance with some exemplary embodiments of the disclosed subject matter.

FIG. 1D schematically illustrates a cross sectional view of an enlarged section of electronic assembly with heat dissipating coating, showing some optional details of the layers, in accordance with some exemplary embodiments of the disclosed subject matter.

FIG. 2A schematically illustrates a cross sectional view of the additional layer, in accordance with some exemplary embodiments of the disclosed subject matter.

FIG. 2B schematically illustrates a cross sectional view of the additional layer, in accordance with some exemplary embodiments of the disclosed subject matter.

FIG. 2C schematically illustrates a cross sectional view of the additional layer, in accordance with some exemplary embodiments of the disclosed subject matter.

FIG. 2D schematically illustrates a cross sectional view of the additional layer, in accordance with some exemplary embodiments of the disclosed subject matter.

FIG. 2E schematically illustrates a cross sectional view of the additional layer, in accordance with some exemplary embodiments of the disclosed subject matter.

FIG. 2F, schematically showing a cross sectional view of the additional layer, in accordance with some exemplary embodiments of the disclosed subject matter.

FIG. 2G schematically illustrates a cross sectional view of the additional layer, in accordance with some exemplary embodiments of the disclosed subject matter.

FIG. 2H schematically illustrates a top view of a section of an additional layer, in accordance with some exemplary embodiments of the disclosed subject matter.

FIG. 3 schematically shows a top view of an electronic assembly with heat dissipating coating, in accordance with some exemplary embodiments of the disclosed subject matter.

FIG. 4, schematically illustrates a top view of a design of an electronic assembly with heat dissipating coating, envisioned as a product, and used for simulating the effectiveness of heat dissipating coating, in accordance with some exemplary embodiments of the disclosed subject matter.

FIG. 5A schematically illustrates an electronic assembly partially coated with heat dissipating coating, prepared and used for measuring the effectiveness of heat dissipating coating, in accordance with some exemplary embodiments of the disclosed subject matter.

FIG. 5B schematically illustrates the top side of the electronic assembly, in accordance with some exemplary embodiments of the disclosed subject matter.

FIG. 5C schematically illustrates the bottom side of the electronic assembly, in accordance with some exemplary embodiments of the disclosed subject matter.

FIG. 6A schematically showing experimental results conducted with the electronic assembly seen in FIGS. 5A-C, in accordance with some exemplary embodiments of the disclosed subject matter.

FIG. 6B schematically shows experimental results conducted with the electronic assembly seen in FIGS. 5A-C, in accordance with some exemplary embodiments of the disclosed subject matter.

### DETAILED DESCRIPTION

Before explaining at least one embodiment of the disclosed subject matter in detail, it is to be understood that the disclosed subject matter is not limited in its application to the details of construction and the arrangement of the components set forth in the following description or illustrated in the drawings. The disclosed subject matter is capable of other embodiments or of being practiced or carried out in various ways. Also, it is to be understood that the phraseology and terminology employed herein is for the purpose of description and should not be regarded as limiting. The drawings are generally not to scale. For clarity, non-essential elements were omitted from some of the drawings.

The terms “comprises”, “comprising”, “includes”, “including”, and “having” together with their conjugates mean “including but not limited to”. The term “consisting of” has the same meaning as “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise. For example, the term “a compound” or “at least one compound” may include a plurality of compounds, including mixtures thereof.

Throughout this application, various embodiments of this disclosed subject matter may be presented in a range format. It should be understood that the description in range format is merely for convenience and brevity and should not be construed as an inflexible limitation on the scope of the disclosed subject matter. Accordingly, the description of a range should be considered to have specifically disclosed all the possible sub-ranges as well as individual numerical values within that range.

It is appreciated that certain features of the disclosed subject matter, which are, for clarity, described in the context of separate embodiments, may also be provided in combination in a single embodiment. Conversely, various features of the disclosed subject matter, which are, for brevity, described in the context of a single embodiment, may also be provided separately or in any suitable sub-combination or as suitable in any other described embodiment of the disclosed subject matter. Certain features described in the context of various embodiments are not to be considered essential features of those embodiments, unless the embodiment is inoperative without those elements.

Similar or identical elements may be marked with letters following the same numeral. A numeral followed by the letter/s “x” refers to any or all of the same type of elements.

In some drawings, containing a plurality of similar or identically elements, only one or a few are marked to avoid clattering the drawings. Marking of elements already marked in pervious drawings may be missing.

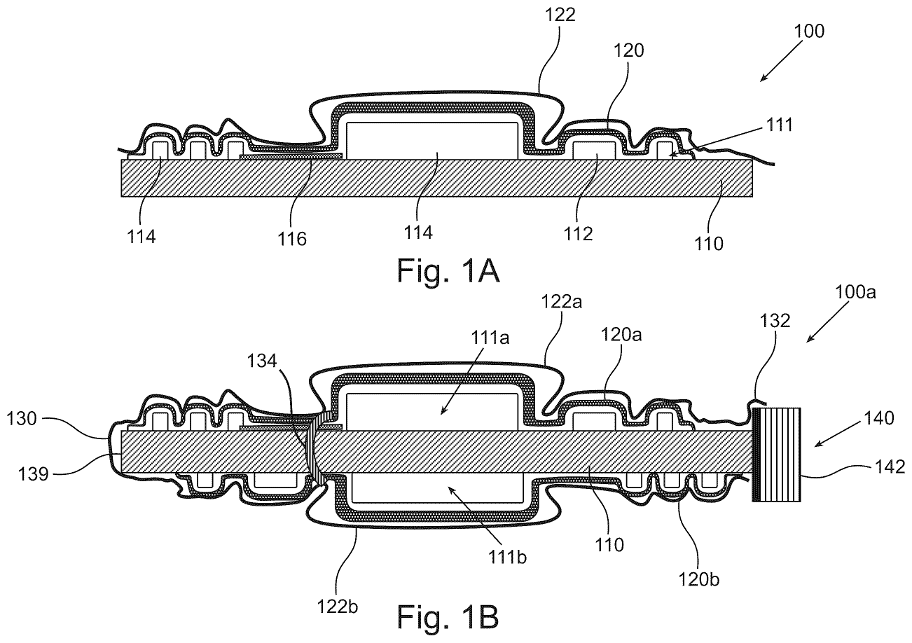

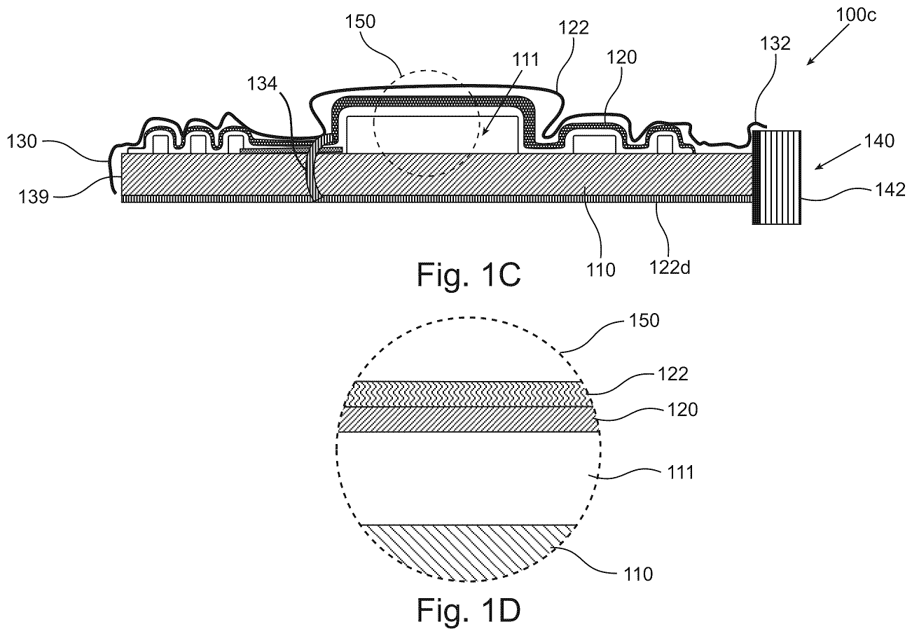

Referring now to FIG. 1A schematically illustrating a cross sectional view of an electronic assembly with heat dissipating coating, in accordance with some exemplary embodiments of the disclosed subject matter.

The electronic assembly with heat dissipating coating 100, comprises PCB assembly substate 110 onto which electrical and mechanical components 111 are positioned. These components include at least one and usually a plurality of electrical components. These components comprise at least one active component 114, at least one passive component 112, other elements soldered to the printed circuit board surface, a combination thereof and the likes. Active components 114 generate heat during operation and are usually the major heat sources; however, passive components 112 such as resistors can generate heat as well although each passive component is usually not a significant heat source, their overall effect does consider as a major heat contributor.

A layer of a thin polymeric film 120 is applied over the electrical and mechanical components 111. The first layer 120 can be applied by methods such as: brushing, spraying, CVD (Chemical vapor deposition), dipping, a combination thereof and the like, in order to protect the board and its components from environmental conditions and from corrosion. Polymeric film 120 may only partially cover electronic assembly, leaving some part of the PCB exposed (for example empty areas, connectors, or exposed traces). In some embodiments, polymeric film 120 comprises a perylene layer. Any type of a perylene can be used (for example but not limited to N, C. D, HT, ParyFree, C-UV, and microRESIST (Registered Trademarks)). It should be noted that perylene provides good electrical isolation, thus it isolates the electronic components and the conductive traces from being shorted by conductive or resistive layer applied on top of the polymeric film 120. Other polymers such as acrylic or polyimide can be used. Optionally, boron-nitride particles can be dispersed within layer 120 since boron-nitride is a very good electrical isolator. Optionally, one or combination of several types of boron-nitride (for example as a-BN, h-BN, c-BN, oe w-BN) can be used. Generally, throughout the text, wherever any of the terms “binder” or “polymer” are used, perylene or perylene mixed with boron-nitride particles can be used. It should be noted that perylene has low thermal conductivity (in the order of 0.08 W/m-K) and thus thin layers are used, or a mixture of perylene and heat conducting particles or flakes (for example, but not limited to boron-nitride particles) where good heat transfer is needed across the layer.

The polymeric film coating 120 is applied and ‘conforms’ to the irregular topography of the PCB substrate 110 and the electrical and mechanical components 111, providing electrical isolation, protecting solder joints, the leads of electronic components, exposed traces, and other metallized areas from corrosion. The polymeric film coating 120 provides operational integrity, covering and ultimately extending the reliability and working life of the electronic assembly 100.

Optionally, the polymeric film coating 120 provides some smoothing of the irregular surface of the electronic and mechanical components 111.

An additional layer 122 having very high thermal conductivity is applied over the layer of the polymeric film coating 120. The additional layer 122 is used for dissipating the heat from the components and controlling the required thermal properties of electrical assembly 100 while increasing the reliability and working life of the electronic assembly.

The additional layer 122 comprises a plurality graphene and/or boron-nitride particles, flakes, or sheets, combination thereof, and the like. The additional layer 122 ‘conforms’ to the irregular topography of the polymeric film coating 120, adheres to it and is in good thermal contact with it. The polymeric film coating 120 is made thin enough so as to conduct heat between the electrical and mechanical components 111 and the additional layer 122. Graphene in the additional layer 122 are electrical conductors and may cause short circuits if applied directly onto the electrical and mechanical components 111, thus it is applied over the insulating polymeric film coating 120.

Each component of electronic assembly 100 operates properly only within a specific temperature range. Additionally, electronic assembly 100 and its electronic components are susceptible to temperature gradients during operation and possibly, also when it is inactive due to differences in expansion coefficients that may cause mechanical stress. Repeated thermal cycling can cause fatigue fractures and failure of components and/or electrical discontinuities.

The heat spreading properties of the additional layer 122 reduces the thermal gradients over the electronic assembly 100 in applications where the electronic assembly is subjected to rapid uneven temperature changes such as in avionic devices that may be subjected to rapid temperature changes as an airplane rapidly ascends or descends.

Additionally, the additional layer 122 spreads heat generated by active components 112 and/or passive components 114 in the electrical and mechanical components 111, and prevents formation of “hot spots” and temperature gradients. Additionally, the additional layer 122 can be used to transfer heat generated by the components to heat sink(s) or cooling units, for example, thermoelectric coolers (TEC), reducing the temperature of the heat generating components.

Referring now to FIG. 1B, schematically illustrating a cross sectional view of an electronic assembly with heat dissipating coating, in accordance with some exemplary embodiments of the disclosed subject matter.

The two-sided electronic assembly with heat dissipating coating 100a comprises PCB assembly substrate 110 having electrical and mechanical components 111a and 111b positioned on its opposing large surfaces.

Thin polymeric film coatings 120a and 120b, respectively are layers that are applied over the corresponding components 111a and 111b on the opposite surfaces.

Additional layers 122a and 112b having very high thermal conductivity are applied, each over the corresponding thin polymeric film coatings 120a and 120b.

FIG. 1B further illustrates a heat sink 140. Such heat sink can be part of the frame or the enclosure holding the two-sided electronic assembly 100a, or can be a dedicated cooling unit, optionally having heat dissipating fins 142, optional fan (not shown in the figure), a TEC unit, a combination thereof and the like. Several heat sinks 140 may be used.

Additional layers 122a and b, respectively, have extensions 132 that form a good thermal contact with heat sink 140.

The additional layers 122a and b can be in thermal contact with each other by thermal bridge 130 over one side 139 of substrate 110. Optionally, additionally, or alternatively, the additional layers 122a and b can be in thermal contact with each other by a thermal bridge 134, thermally connecting the two layers via the substrate 110. Thermal bridges 130 and/or 134 can be extensions of the additional layers, or made of other heat conducting materials such as metal. Depending on the electronic elements near thermal bridges 130 and/or 134, the films may be applied before applying the thermal bridges, or it may be missing. Several thermal bridges 130 and/or 134 may be used.

Referring now to FIG. 1C, schematically illustrating a cross sectional view of an electronic assembly with heat dissipating coating, in accordance with some exemplary embodiments of the disclosed subject matter.

The one-sided electronic assembly with heat dissipating coating 100c comprises PCB assembly substrate 110 onto which electrical and mechanical components 111 are disposed similarly to electronic assembly 100 of FIG. 1A. Thin polymeric film coatings 120 covers the components 111 onto which an additional layer 122 is placed; however, an additional layer 122d is applied to the opposing surface of substrate 110, onto which no electronic components are placed.

Thermal bridge 130 and/or 134 are used to transfer heat from the heat generating electric and mechanical components 111 to the additional layer 122d. Heat is also transferred through the substrate 110. The additional layer 122d can be made thicker than the additional layer 122 that is disposed on the components 111, and may have better heat transferring properties as it does not have to conform to uneven components height and thus is generally flat.

Depending on the electronic pads, contacts and conductors, a polymeric film coating (not seen in this figure) can be applied before applying the additional layer 122d.

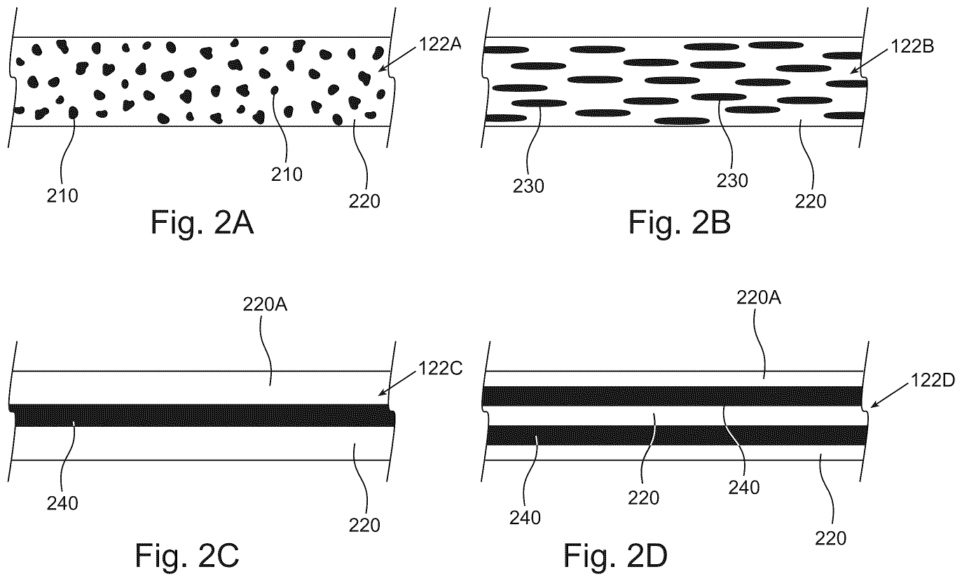

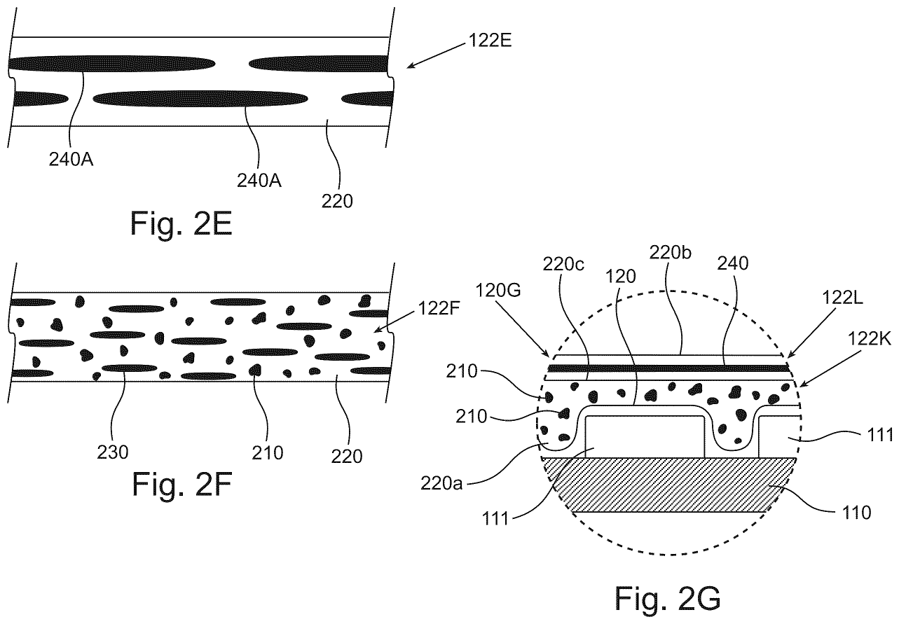

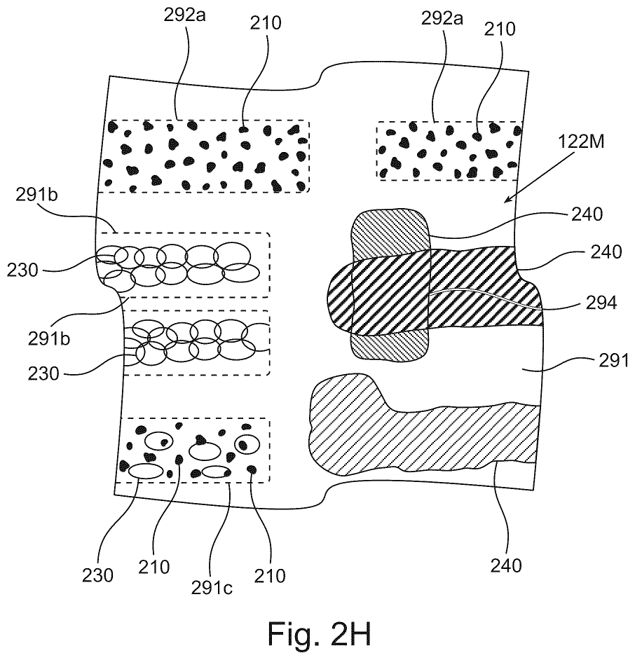

Zone 150 is seen in enlargement in FIGS. 2A-G to better show some optional details of the first, second and third layers.

Referring now to FIG. 1D, schematically illustrating a cross sectional view of an enlarged section 150 of electronic assembly with heat dissipating coating, showing some optional details of the layers that are applied on the substrate, in accordance with some exemplary embodiments of the disclosed subject matter.

In the following FIGS. 2A to 2G, several options of the additional layer are illustrated:

Referring now to FIG. 2A schematically illustrating a cross sectional view of the additional layer, in accordance with some exemplary embodiments of the disclosed subject matter.

Additional layer 122A comprises high thermal conductivity particles 210 such as graphene or boron-nitride, or a mixture of both in a matrix of binder 220. The ratio of the parts can vary according to need.

Mixture of high thermal conductivity particles 210 and liquid binder can be prepared and applied over the film and let solidified. Alternatively, particles can be dispersed first, and the liquid binder sprayed over them and let harden. Alternatively, liquid binder applied over the polymeric film coating and the particles disperse so as to adhere to the binder. Other methods of application can be used without limiting the scope of the present subject matter. Optionally, the additional layer can be prepared as a thin membrane and glued to the film.

Referring now to FIG. 2B schematically illustrating a cross sectional view of the additional layer, in accordance with some exemplary embodiments of the disclosed subject matter.

Additional layer 122B comprises high thermal conductivity flakes 230 such as graphene or boron-nitride, or a mixture of both in a matrix of binder 220. The ratio of the parts can vary according to need.

Preferably, the flakes are oriented substantially parallel to the additional layer, and are partially overlapping to provide good heat conductivity along the additional layer. This configuration is ensured by having the thickness of the additional layer comparable or smaller than the larger dimension of the flakes. Optionally, the binder hardens by evaporation of solvent, thus the thickness of the additional layer decreases and the flakes get oriented substantially parallel to the additional layer. Optionally, the additional layer can be prepared as a thin membrane and glued to the second layer.

Referring now to FIG. 2C schematically illustrating a cross sectional view of the additional layer, in accordance with some exemplary embodiments of the disclosed subject matter.

Additional layer 122C comprises a single sheet 240 made of material having high thermal conductivity such as graphene or boron-nitride sheet. The single sheet 240 of high thermal conductivity can be embedded in the polymeric film coating using a binder 220. Alternatively, the single sheet of high thermal conductivity is placed over the polymeric film coating while the polymeric film coating is in liquid or semi-liquid state and adheres to the polymeric film coating. This process can be vacuum assisted to eliminate air babbles between the film coating and additional layer. Optionally, a protective coating 220A is applied over the single sheet 240 of high thermal conductivity. Optionally, the same material is used as both binder 220 and protective coating 220A. Optionally, the additional layer can be prepared as a thin membrane and glued to the polymeric film coating.

Referring now to FIG. 2D schematically illustrating a cross sectional view of the additional layer, in accordance with some exemplary embodiments of the disclosed subject matter.

Additional layer 122D comprises two parallel sheets 240 of material having high thermal conductivity such as graphene or boron-nitride sheets. The sheets 240 of high thermal conductivity can be embedded in the polymeric film coating and to each other using a binder 220. Optionally, a protective coating 220A is applied over the two sheets 240 of high thermal conductivity material. Optionally the same material is used as both binder 220 and protective coating 220A. Optionally, the additional layer can be prepared as a thin membrane and glued to the polymeric film coating.

Referring now to FIG. 2E schematically illustrating a cross sectional view of the additional layer, in accordance with some exemplary embodiments of the disclosed subject matter.

Additional layer 122E comprises high thermal conductivity sheets 240A such as graphene or boron-nitride, or a mixture of both in a matrix of binder 220.

Preferably, high thermal conductivity sheets 240A are partially overlapping to provide good heat conductivity along the additional layer. Optionally each sheet is individually placed. Optionally, the additional layer can be prepared as a thin membrane and embedded in to the polymeric film coating,

Referring now to FIG. 2F schematically illustrating a cross sectional view of the additional layer, in accordance with some exemplary embodiments of the disclosed subject matter.

Additional layer 122F comprises a mixture of high thermal conductivity flakes 230 and high thermal conductivity particles 210 in a matrix of binder 220. The high thermal conductivity flakes 230 and high thermal conductivity particles 210 can be made of graphene or boron-nitride, or a mixture of both.

Mixture of high thermal conductivity flakes 230, high thermal conductivity particles 210, and liquid binder may be prepared and applied over the polymeric film coating and let solidified. Optionally, the additional layer can be prepared as a thin membrane and embedded in to the polymeric film coating,

Referring now to FIG. 2G, schematically showing a cross sectional view of the additional layer, in accordance with some exemplary embodiments of the disclosed subject matter.

Additional layer 122G comprises an additional lower layer 122K comprising high thermal conductivity particles 210 in a matrix of binder 220a is applied to the polymeric film coating 120 to substantially fill the gaps and smoothen the surface of the polymeric film coating 120 that conforms to the irregular structure of the electrical and mechanical components 111. This provides a smooth surface on which an upper layer 122L comprising a single sheet of high thermal conductivity 240 is provided. Optionally, multiple sheets of high thermal conductivity material are used in upper layer 122L.

Lower layer 122K can be applied in liquid form while surface tension causes its surface to become smooth. A sheet of high thermal conductivity 240 can be placed over the lower layer 122K and adhered to it. Alternatively, a binder 220c can be used for gluing the sheet of high thermal conductivity 240 to the lower layer 122K. Optionally, a protective coating 220b is applied over the single or multiple sheets of high thermal conductivity 240.

Referring now to FIG. 2H, schematically showing a top view of a section of an additional layer, in accordance with some exemplary embodiments of the disclosed subject matter.

Additional layer 122M shows several optional possibilities to arrange the high thermal conductivity material so as to provide differential and/or directional heat transfer within the additional layer. It should be noted that while several possibilities are seen within the same figure, any one or combination of few optional possibilities can be used.

In order to provide differential and/or directional heat transfer within the additional layer 122M, at least one or a plurality of low thermal conductivity zone 291 are left without high thermal conductivity material, or with lower density of high thermal conductivity material.

For example, high thermal conductivity zones 292a, can be formed, each comprising a plurality of high thermal conductivity particles 210, wherein the zones 292a are separated by low thermal conductivity zone 291.

Similarly, high thermal conductivity zones 292b can be formed, each comprising a plurality of high thermal conductivity flakes 230, wherein the zones 292b are separated by low thermal conductivity zone 291 from other high thermal conductivity zones 292a, b, or c.

Similarly, high thermal conductivity zones 292c can be formed, each comprising a plurality of high thermal conductivity flakes 230 and high thermal conductivity particles 210, wherein the zones 292c are separated by low thermal conductivity zone 291 from other high thermal conductivity zones 292a and b.

Additionally and optionally, a single sheet of high thermal conductivity material 240 can be placed in one or a few areas of additional layer 122M.

Additionally and optionally, at least two sheets of high thermal conductivity material 240 can be placed such as to form, at least partially, overlapping zone 294, in one or a few areas of additional layer 122M. The overlapping zone 294 forms an area of higher thermal conductivity. Additionally, the overlapping zone 294 forms a thermal bridge between the non-overlapping sections of the sheets of high thermal conductivity material 240, thus forming a high thermal conductivity zone that is larger than each of the partially overlapping sheets of high thermal conductivity material 240.

Combinations and partial overlapping of the abovementioned zones can be used depending on the thermal dissipation requirements.

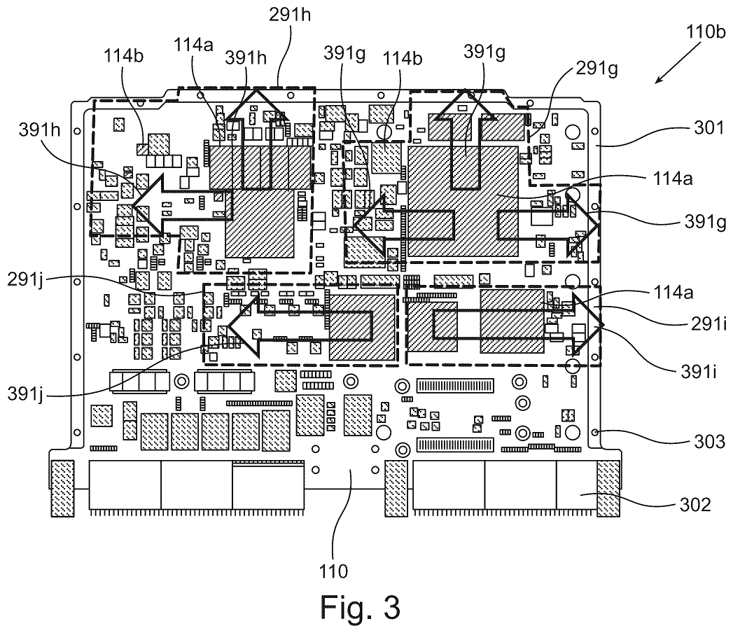

Referring now to FIG. 3 schematically showing a top view of an electronic assembly with heat dissipating coating, in accordance with some exemplary embodiments of the disclosed subject matter.

Electronic assembly with heat dissipating coating 100b comprises a PCB substrate 110 on which electronic components 114a and 114b are soldered. In this example, electronic components 114a are highly heat producing components, for example power components or processors, while electronic components 114b are low heat producing components. Metal frame 301 performs functions that related to EMI and electrical potential ground as well as mechanical anchoring and support. Electronic assembly with heat dissipating coating 100b has electrical connectors 302 on one side, and a metallic frame 301 on the other three sides. The metallic frame 301 optionally also acts as a heat sink and is having mounting holes 303 so as to mount the electronic assembly to a rake or enclosure (not seen herein) that may also act as a heat sink.).

It should be noted as graphene is electrical conductor, the graphene layer may act as EMI (electromagnetic interference) isolator. By optionally grounding, or at least capacitively grounding the graphene sheets, a “Faraday cage” may be formed for protecting the electronics. In contrast, the polymeric matrix may be made electrically isolating. Alternatively, the matrix may be made to have good, or at least some electrical conductivity so as to complete the electrical connection between adjacent graphene particle, sheets or plates, thus enhancing the EMI protection.

As mentioned herein before, after the polymeric film coating is applied, an additional layer is applied, which has heat spreading zones, in this case, zones 391g-j. This can be performed by applying the additional layer only over the heat spreading zones 391g-j, or by embedding the high heat conducting materials in the heat spreading zones 391g-j. Each of arrows 391g-j shows the direction of the heat transfer in the corresponding heat spreading zones 391g-j. Note that in heat spreading zone 391i, heat is essentially transferred from highly heat producing components to the frame; in heat spreading zones 391g and 391h, heat is essentially transferred from highly heat producing components to both the colder areas in which the components are producing less heat; and in heat spreading zone 391j, heat is essentially transferred from highly heat producing components to the colder area with heat producing components that produces less heat that the highly heat producing components.

The composition of the heat spreading zones 391g-j can be identical, similar, or dissimilar to each other.

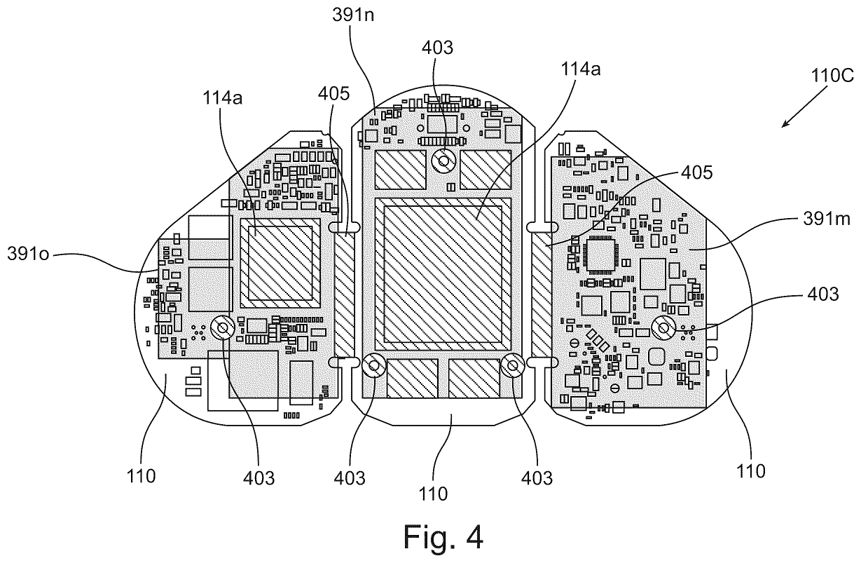

Referring now to FIG. 4A, schematically illustrating a top view of a design of an electronic assembly with heat dissipating coating, envisioned as a product, and used for simulating the effectiveness of heat dissipating coating, in accordance with some exemplary embodiments of the disclosed subject matter.

Electronic assembly with heat dissipating coating 100c comprises three PCB substrates 110, joined by bridges 405. Electronic components 114a are soldered to the PCB substrates 110. In this example, two electronic components 114a are highly heat producing components, while the other electronic components are of low heat producing components. Electronic assembly with heat dissipating coating 100c is having mounting holes 403 that also act as mechanical connecting holes for heat sink assembly.

After the polymeric film coating is applied, an additional layer is applied having heat spreading zones 391m-o, each comprising plurality of graphene and/or boron-nitride particles, sheets or flakes.

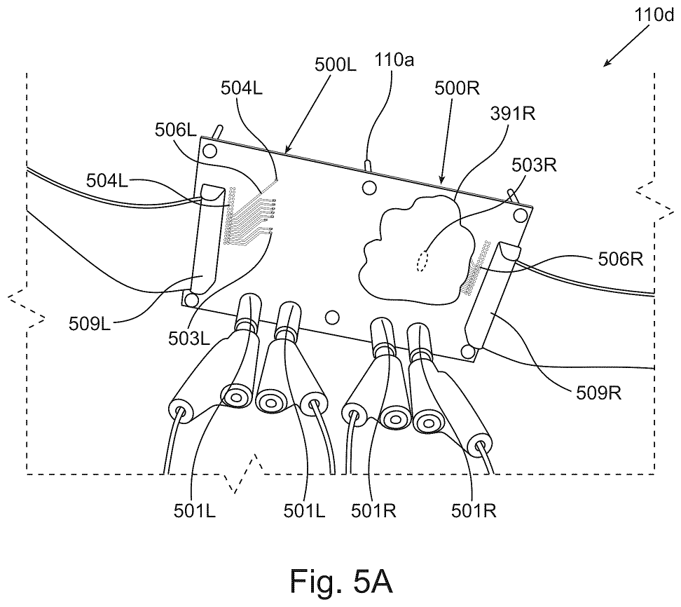

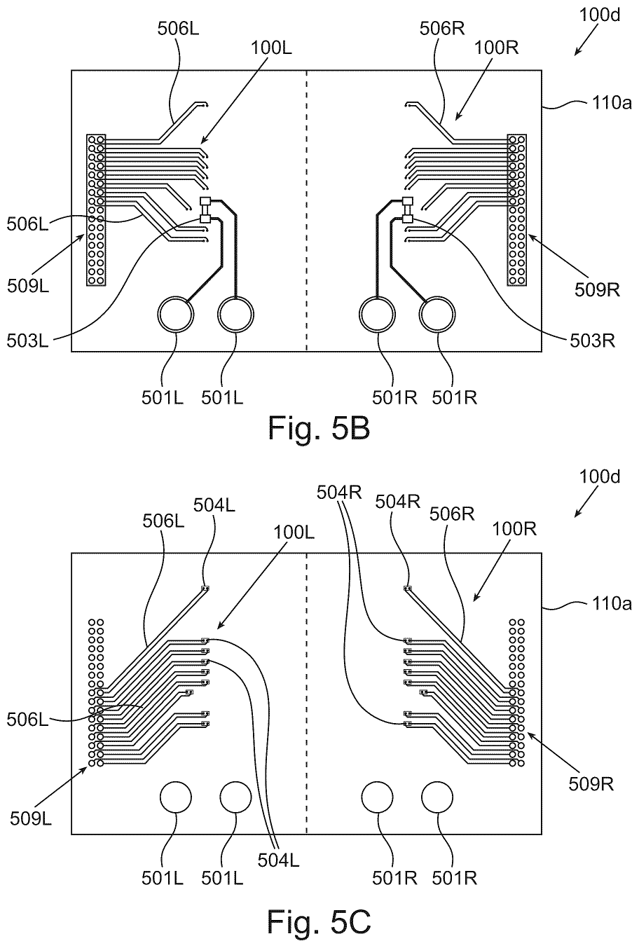

Referring now to FIG. 5A schematically showing an electronic assembly 100d partially coated with heat dissipating coating prepared and used for measuring the effectiveness of heat dissipating coating, in accordance with some exemplary embodiments of the disclosed subject matter.

Electronic assembly partially coated with heat dissipating coating 100d was constructed as an assembly on a single PCB substrate 110a, with two mirror symmetrical electronic units 500L and 500R for the left and right sides, respectively. Note that in these figure numbers followed by the letters “L” and “R” corresponds to identical elements in the left and right side respectively, and thus explanation need not be repeated. A substrate 110 having very low thermal conductivity was used in order to measure and analyze the thermal conductivity of the coating 391R appliqued as an additional layer patch to the right-hand side electronic units 100d

PCB substrate 110a comprises left and right power connectors 501L and 501R for left and right-side units 500L and 500R, respectively, to provide power to power resistors 503L and 503R (cannot be seen since it is below the highly heat conducting coating 391R).

Data collecting connector 509L connects a plurality of temperature sensors 504L (thermistors in this example), located at different distances from power resistor 503L, via two-sided conductive traces 506L (only few of the traces and sensors are marked to avoid cluttering the drawings). Conductive copper traces of 0.5 oz. per feet square were used.

The entire substrate and the electrical and mechanical components are comprising the traces and the pads. Thermistors and power resistors were covered with a polymeric film coating of 20 um parylene conformal coating.

The Right electronic unit 100R was partially coated with a patch of highly thermal conduction material-additional layer 391R of conformal coating comprising 5% (by volume, or alternatively by weight) graphene nano-platelets mix with acrylic coating layer of thickness between 30 to 60 um.

Referring now to FIG. 5B schematically illustrating the top side of the electronic assembly 100d, in accordance with some exemplary embodiments of the disclosed subject matter.

The drawing shows the positions of the conductive traces, the connectors and the power transistors on substrate 100d.

Referring now to FIG. 5C schematically illustrating the bottom side of the electronic assembly 100d, in accordance with some exemplary embodiments of the disclosed subject matter.

The drawing shows the positions of the conductive traces, the connectors and the temperature sensors on substrate 100d.

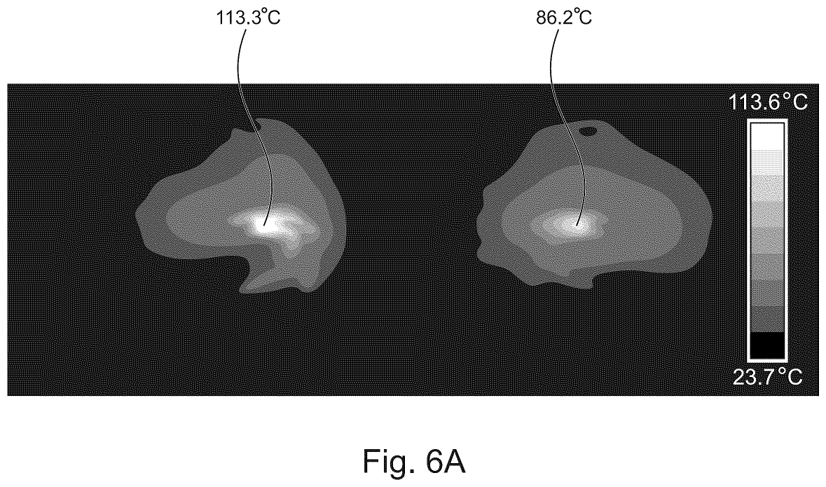

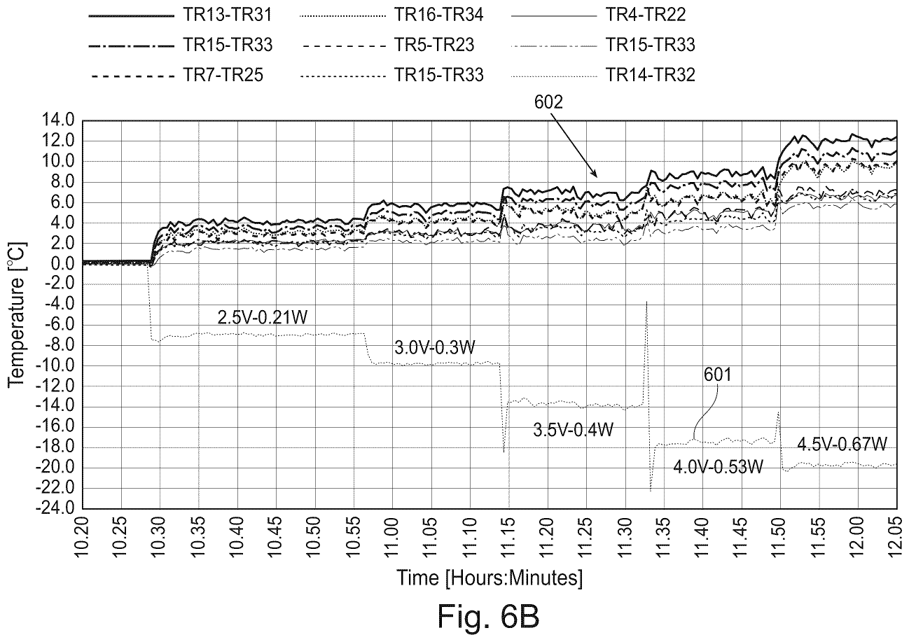

Referring now to FIG. 6A schematically showing experimental results conducted on the electronic assembly seen in FIGS. 5A-C, in accordance with some exemplary embodiments of the disclosed subject matter.

FIG. 6A shows an image taken by an infra-red (IR) thermal camera, showing the temperature distribution over the surface of the bottom side of the test board of the electronic assembly 100d, during operation. Note the high maximum temperature of 113.3 degree centigrade, and larger hot spot over the left side which was not coated with an additional layer of highly conductive material, vs. the lower maximum temperature of 86.2 degree centigrade, and smaller hot spot over the right side which was coated with an additional layer of highly conductive material layer 503R.

From these experimental results it was calculated that the heat spreading properties of the heat spreading layer is about 10 W m(−1) K(−1). Spreading the heat generated by the heat producing element 503R by the heat spreading layer, cases a reduction of about 27 degrees in the maximum temperature over the right hand side of the electronic assembly 100d, in comparison to the left hand side where heat spreading layer was not applied.

Referring now to FIG. 6B schematically showing experimental results conducted on the electronic assembly seen in FIGS. 5A-C, in accordance with some exemplary embodiments of the disclosed subject matter.

FIG. 6B shows a time sequence graph, showing the temp differences between a pair of corresponding thermistors in the graphene coating side and a thermistor on the graphene-free side on the same location as seen in FIG. 5C, as the power generated by power resistor 503R and 503L is incremented from zero to 0.67 watt.

The lower line 601 shows the temperature difference between the TR14 and TR32 thermistors that are located on the bottom side of the substrate below the power resistor 503R and 503L, respectively. As can be seen, the additional layer of highly conductive material layer 503R removes the heat generated by the power resistor 503R and 503L, lowering the temperatures under the power resistor on the right side.

The upper lines 602 show the temperature difference between thermistors that are located on the bottom side of the substrate further from the power resistors 503R and 503L, respectively. As can be seen, the additional layer of highly conductive material 503R spreads the heat generated by the power resistor 503R while increasing the temperatures at locations further from the power resistor on the right side.

Main conclusion from the experiments is that a 5% (by volume, or alternatively by weight in respect to the binder) graphene layer provides a significant thermal spreading, causing approximately 20% reduction in the temperature of the hottest component closest to the heat source and increase of the temperature of the peripheral thermistors of about 20%.

Production and dimensions of highly conductive material to be used within the exemplary embodiments of the disclosed subject matter:

Particles, flaks and sheets of both graphene and boron-nitride can be produced in verity of dimensions, depend on the production method, capabilities and requirements. Among the methods of production graphene are:

1) Bottom-Up route in which a carbonaceous gas source is used to produce graphene in methods such as chemical vapor deposition (CVD). CVD is considered the most extensively used to synthesize large amounts of high-quality graphene sheets. Using this method, a single-atom-thick sheet of hexagonally arranged atoms is produced.

2) Top-Down route is based on the attack of graphite, which is used as raw material, to break the layers forming the graphene sheets. Methods such as micromechanical cleavage, exfoliation of graphite intercalation compounds (GICs), graphene oxide exfoliation, and solvent-base exfoliation are used for synthesizing graphene-based powder of textures agglomerates materials made of single layer flakes that are stacked or can be broken to small particles.

In a non-limiting example, a single layer graphene sheet measuring 6 cm by 5 cm, having thickness of 0.3 nm was used. Other sheet dimensions can be used depending on the requirements.

In another non-limiting example, grapheme powder was used. Few additional layers were prepared using graphene flakes having platelet shape with average thickness of approximately 15 nm and average particle diameters of 5, 15, and 25 microns were mixed with acrylic binder to form the additional layers having thickness between 30 to 60 microns. Other flakes dimensions and/or layer thicknesses can be used, depending on the requirements. Binders other than acrylic may be used.

Several patterns of layers can be used, and all falls within the exemplary embodiments of the disclosed subject matter:

1) A layer of thin polymeric film can be applied on a printed circuit board (PCB) by brushing, spraying, CVD, or dipping a printed circuit board in liquid, in order to provide electrical insolation and protect the board and its components from environmental and corrosion.

2) An additional layer of graphene flakes can be embedded within a polymeric matrix of the conformal coating applied over the polymeric film to improve thermal conductivity of the additional layer.

3) Ggraphene monolayers or multi layers applied over the polymeric film to improve thermal conductivity of the additional layer,

4) Boron-nitride flakes can be embedded within the polymeric matrix of a conformal coating applied over the polymeric film to improve thermal conductivity and electrical insulation of the additional layer.

5) Boron-nitride monolayers or multi layers can be applied over the polymeric film to improve thermal conductivity and electrical insulation of the additional layer.

Note that when small graphene particles are dispersed within a polymer matrix, the layer thus created may be electrical insulating as the small graphene particles do not create a contiguous electrical connection. Such coating can be applied directly over exposed electrical contacts and traces without creating electrical shorts.

In contrast, when larger graphene particles, flakes or sheets are used, an electrically isolating layer is preferably applied over exposed electrical contacts and traces to prevent electrical shorts.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

1. An electronic assembly with heat spreading coating comprising:
a printed circuit board (PCB) having electric conducting traces and at least one heat producing electronic component;
an electrically isolating polymeric coating applied over the electric conducting traces and the at least one heat producing electronic component, wherein the polymeric coating comprises parylene, and wherein the polymeric coating at least partially covers the PCB, and wherein the electrically isolating polymeric coating conforms with an irregular structure of the PCB;
a first heat spreading layer, applied over the polymeric coating, comprises:
at least one heat spreading zone selected from the group consisting of:
a plurality of graphene nano-platelets, a plurality of graphene particles, a plurality of boron-nitride particles, a plurality of graphene flakes, a plurality of boron-nitride flakes, at least one graphene sheets, and combination thereof; and
a binder,
wherein the electrically isolating polymeric coating adheres to the PCB and covers the electric conducting traces and the at least one heat producing electronic component, and the first heat spreading layer conforms to the irregular structure of the polymeric coating.

2. (canceled)

3. The electronic assembly with heat spreading coating of claim 1, wherein a thickness of the electrically isolating polymeric coating is less than 60 microns.

4. (canceled)

5. The electronic assembly with heat spreading coating of claim 1, wherein the electrically isolating polymeric coating is applied using at least one of: spraying, brushing, dipping, CVD (chemical vapor deposition).

6. The electronic assembly with heat spreading coating of claim 1, wherein thermal conductivity of the first heat spreading layer is more than 3 W m(−1) K(−1).

7. (canceled)

8. The electronic assembly with heat spreading coating of claim 1, wherein
at least one of said graphene particles and said boron-nitride particles have a range of sizes of between 3 to 35 microns.

9. (canceled)

10. (canceled)

11. (canceled)

12. The electronic assembly with heat spreading coating of claim 1, wherein the first heat spreading layer comprises at least one of: plurality of graphene flakes, and plurality of boron-nitride flakes, wherein the fakes in said plurality of the graphene flakes are oriented substantially in a plane of the first heat spreading layer, and the plurality of the graphene flakes partially overlap.

13. The electronic assembly with heat spreading coating of claim 12, wherein the plurality of the graphene flakes partially overlap such that at least three flakes overlap at the same place.

14. The electronic assembly with heat spreading coating of claim 1, wherein the first heat spreading layer comprises at least two graphene sheets.

15. The electronic assembly with heat spreading coating of claim 14, wherein said at least two graphene sheets partially overlap.

16. The electronic assembly with heat spreading coating of claim 8, wherein said first heat spreading layer substantially fills gaps between said heat producing electronic components and provides a smooth surface away from the PCB.

17. The electronic assembly with heat spreading coating of claim 16, further comprising at least a second heat spreading layer applied on a surface of the first heat spreading layer and wherein the second heat spreading layer comprises at least one graphene sheet.

18. (canceled)

19. (canceled)

20. (canceled)

21. The electronic assembly with heat spreading coating of claim 17, further comprising a third heat spreading layer, wherein the third heat spreading comprises at least one graphene sheet.

22. (canceled)

23. The electronic assembly with heat spreading coating of claim 21, further comprising a protective coating applied over the first heat spreading layer and/or the second heat spreading layer and/or the third heat spreading layer.

24. The electronic assembly with heat spreading coating of claim 21, wherein the binder is a layer applied between the first heat spreading layer and the second heat spreading layer and/or applied between the second and the third heat spreading layers.

25. The electronic assembly with heat spreading coating of claim 1, wherein the heat spreading zone spreads the heat generated by the least one heat producing electronic component, wherein, in operation, a temperature of the at least one heat producing electronic component is at least 10 degrees Centigrade below the temperature of the same PCB in which a heat spreading layer was not applied.

26. (canceled)

27. The electronic assembly with heat spreading coating of claim 1, wherein, in operation, the temperature of the at least one heat producing electronic component is at least 5% below a temperature of the same PCB in which a heat spreading layer was not applied.

28. (canceled)

29. The electronic assembly with heat spreading coating of claim 1, wherein the first heat spreading layer comprises at least one graphene sheet, and wherein a length and a width of the at least one graphene sheet is between 1 to 10 cm.

30. The electronic assembly with heat spreading coating of claim 29, wherein a thickness of the at least one graphene sheet is 0.3 nm.

31. The electronic assembly with heat spreading coating of claim 1, wherein the first heat spreading layer is a conformal coating layer comprising 5% by weight or by volume of graphene nano-platelets mix with the binder, and the conformal coating layer has thickness between 30 to 60 microns.

32. (canceled)

33. The electronic assembly with heat spreading coating of claim 1, wherein a thickness of the first heat spreading layer is between 30 to 60 microns.

34. (canceled)

35. (canceled)

36. (canceled)

37. The electronic assembly with heat spreading coating of claim 1, wherein the first heat spreading layer comprises at least two non-contiguous heat spreading zones, wherein each of the at least two non-contiguous heat spreading zones comprises at least one graphene sheet, such that the graphene sheets of different heat spreading zones do not overlap.

38. (canceled)

39. (canceled)

40. (canceled)
